(19) United States
(12) Patent Application Publication
(10) Pub. No.: US 2023/0411882 A1
(43) Pub. Date: Dec. 21, 2023

(54) SINGLE-SLOT PCIE CARD WITH EXPANDED MEMORY

(71) Applicant: SMART Modular Technologies, Inc., Newark, CA (US)

(72) Inventors: JINYING SHEN, SAN RAMON, CA (US); KWANG JIN GOOI, Pulau Pinang (MY)

(21) Appl. No.: 18/087,198

(22) Filed: Dec. 22, 2022

Related U.S. Application Data
(60) Provisional application No. 63/353,262, filed on Jun. 17, 2022.

(51) Int. Cl. H01R 12/73; H01R 25/00; H05K 1/02; H05K 1/18

(52) U.S. Cl. CPC H01R 12/737; H01R 25/006; H05K 1/0278; H05K 1/189; H05K 2201/10189; H05K 1/117

(57) ABSTRACT

A single-slot peripheral component interconnect express (PCIe) card with expanded memory is provided. Embodiments described herein use two rigid circuit boards which are oriented perpendicular to each other. The two rigid circuit boards are connected by a flexible cable, which can be sandwiched between the laminates of the rigid boards. The flexible cable further provides high-speed signal connection and high-power connection between the two rigid boards. In addition, the two rigid boards can be secured by two mechanical retainers. This approach enables a PCIe card to have three or more (e.g., four) dual in-line memory modules (DIMMs) while meeting the PCIe standard for single slot primary side height by placing the DIMM sockets horizontally, thus lowering the overall height of the PCIe card.

### FIELD OF THE DISCLOSURE

The present disclosure relates to peripheral component interconnect express (PCIe) cards.

### BACKGROUND

Electronic devices and systems are increasing in complexity and computation power, and often require additional system resources to support modern computing applications. Many of these applications deal with large amounts of data, thus requiring additional resources (e.g., memory and processing power) to efficiently perform computations. In this regard, computer processors and support systems are evolving to provide more computation throughput in smaller packages. Further, many computer systems include parallel architectures and processors to increase the available resources for computations.

Computer memory chips are being developed with higher density and transistor counts for devices. Standardization within the computing industry has also resulted in the creation of standardized memory products having quantized sizes and capacities. Modern computer systems often use these and other standardized components. Thus, increased memory size is often achieved by increasing the size or number of such memory chips, increasing the size of the underlying support architectures.

FIG. 1A is a schematic diagram of a dual in-line memory module (DIMM) 10. FIG. 1B is a schematic diagram of a DIMM socket 12. The DIMM is a standardized size of removable memory module mounted on a printed circuit board (PCB), which fits into the DIMM socket 12. DIMM 10 is natively 64 bits, providing for high-speed data transfer between the memory and other components of a computing system.

FIG. 1C is a schematic diagram of a peripheral component interconnect express (PCIe) card 14. PCIe is a high-speed serial computer expansion bus standard in which PCIe cards 14 have a standardized size to interface with other components in a computing system (e.g., through a computer motherboard). PCIe cards 14 can take one or multiple slots, but must adhere to a maximum primary side height of 14.47 millimeters (mm) for single slot, 34.80 mm for dual slot, or 55.12 mm for triple slot.

FIG. 2A is a schematic diagram of a PCIe memory card 16 with vertically mounted DIMM sockets 12. FIG. 2B is a side view of the PCIe memory card 16 of FIG. 2A. Because the PCIe standard does not allow for components to extend past the footprint illustrated in FIG. 1C, this restricts how many DIMM sockets 12 can be mounted to the PCIe memory card 16. In order to provide multiple DIMM sockets 12 (e.g., 4 in the illustrated example), manufacturers may use vertically mounted DIMM sockets 12. However, as illustrated in FIG. 2B, once the DIMM 10 is inserted into the DIMM socket 12, the primary side height of the PCIe memory card 16 is 31.90 mm, making it a dual slot PCIe card since it exceeds the maximum of 14.47 mm for single slot.

FIG. 3A is a schematic diagram of a PCIe memory card 18 with angle-mounted DIMM sockets. FIG. 3B is a side view of the PCIe memory card 18 of FIG. 3A. Another approach to providing multiple DIMM sockets 12 on the PCIe memory card 18 is to use angle-mounted DIMM sockets 12. However, once the DIMM 10 is inserted into the DIMM socket 12, the primary side height of the PCIe memory card 16 is 17.01 mm, making it a dual slot PCIe card since it exceeds the maximum of 14.47 mm for single slot

### SUMMARY

A single-slot peripheral component interconnect express (PCIe) card with expanded memory is provided. Embodiments described herein use two rigid circuit boards which are oriented perpendicular to each other. The two rigid circuit boards are connected by a flexible cable, which can be sandwiched between the laminates of the rigid boards. The flexible cable further provides high-speed signal connection and high-power connection between the two rigid boards. In addition, the two rigid boards can be secured by two mechanical retainers. This approach enables a PCIe card to have three or more (e.g., four) dual in-line memory modules (DIMMs) while meeting the PCIe standard for single slot primary side height by placing the DIMM sockets horizontally, thus lowering the overall height of the PCIe card.

An exemplary embodiment provides a PCIe card. The PCIe card includes a first circuit board comprising a PCIe connector and a second circuit board electrically connected with the first circuit board and angled transverse to the first circuit board, the second circuit board comprising a DIMM socket.

Another exemplary embodiment provides a single-slot PCIe card. The single-slot PCIe card includes a first circuit board comprising a PCIe connector and a second circuit board electrically connected with the first circuit board and comprising three or more DIMM sockets.

Another exemplary embodiment provides a computer peripheral card. The computer peripheral card includes a first circuit board comprising laminate layers and a second circuit board angled transverse to the first circuit board, the second circuit board comprising a memory module connector. The computer peripheral card further includes a flexible electrical connection between the first circuit board and the second circuit board, wherein the flexible electrical connection exits the first circuit board between the laminate layers of the first circuit board.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a schematic diagram of a dual in-line memory module (DIMM).

FIG. 1B is a schematic diagram of a DIMM socket.

FIG. 1C is a schematic diagram of a peripheral component interconnect express (PCIe) card.

FIG. 2A is a schematic diagram of a PCIe memory card with vertically mounted DIMM sockets.

FIG. 2B is a side view of the PCIe memory card of FIG. 2A.

FIG. 3A is a schematic diagram of a PCIe memory card with angle-mounted DIMM sockets.

FIG. 3B is a side view of the PCIe memory card of FIG. 3A.

FIG. 4A is a schematic diagram of a single-slot PCIe card with expanded memory according to embodiments described herein.

FIG. 4B is a side view of the single-slot PCIe card of FIG. 4A.

FIG. 4C is an expanded side view of the single-slot PCIe card of FIG. 4A.

FIG. 4D is another expanded side view of the single-slot PCIe card of FIG. 4A.

FIG. 5A is a side view of the single-slot PCIe card with a second circuit board aligned with a first circuit board.

FIG. 5B is a side view of the single-slot PCIe card with the second circuit board transverse to the first circuit board.

FIG. 5C is a side view of the single-slot PCIe card with the second circuit board secured to the first circuit board with a mechanical retainer.

FIG. 6A is a schematic diagram of the single-slot PCIe card with the second circuit board secured to the first circuit board with mechanical retainers.

FIG. 6B is a side view of the mechanical retainer securing the second circuit board to the first circuit board.

FIG. 6C is an isometric view of the mechanical retainer securing the second circuit board to the first circuit board.

FIG. 6D is a top view of the mechanical retainer securing the second circuit board to the first circuit board.

FIG. 7A is a top view of a memory expansion card according to embodiments described herein.

FIG. 7B is a side view of the memory expansion card of FIG. 7A.

FIG. 7C is a top isometric view of the memory expansion card of FIG. 7A.

FIG. 7D is a bottom isometric view of the memory expansion card of FIG. 7A.

FIG. 8 is a block diagram of a computer system according to embodiments disclosed herein.

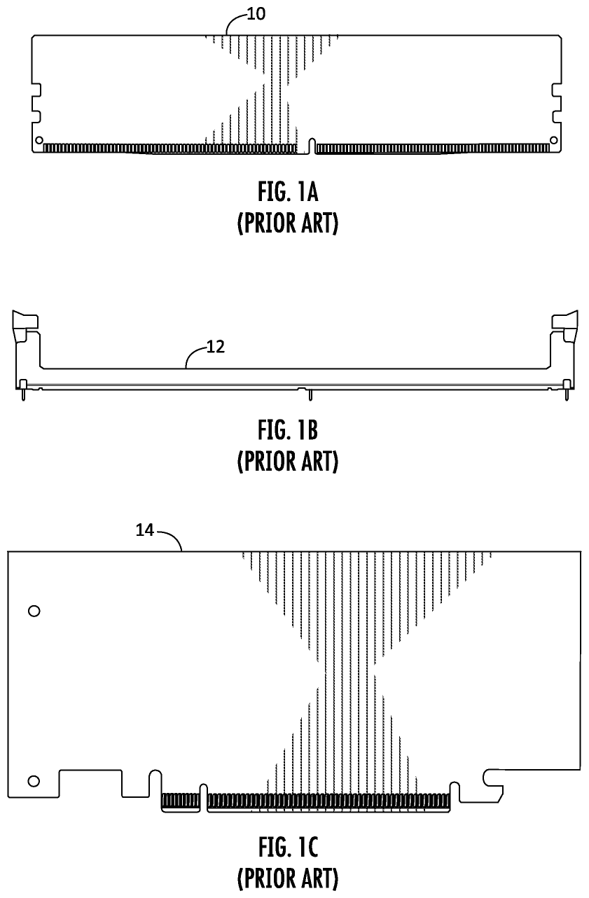

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

A single-slot peripheral component interconnect express (PCIe) card with expanded memory is provided. Embodiments described herein use two rigid circuit boards which are oriented perpendicular to each other. The two rigid circuit boards are connected by a flexible cable, which can be sandwiched between the laminates of the rigid boards. The flexible cable further provides high-speed signal connection and high-power connection between the two rigid boards. In addition, the two rigid boards can be secured by two mechanical retainers. This approach enables a PCIe card to have three or more (e.g., four) dual in-line memory modules (DIMMs) while meeting the PCIe standard for single slot primary side height by placing the DIMM sockets horizontally, thus lowering the overall height of the PCIe card.

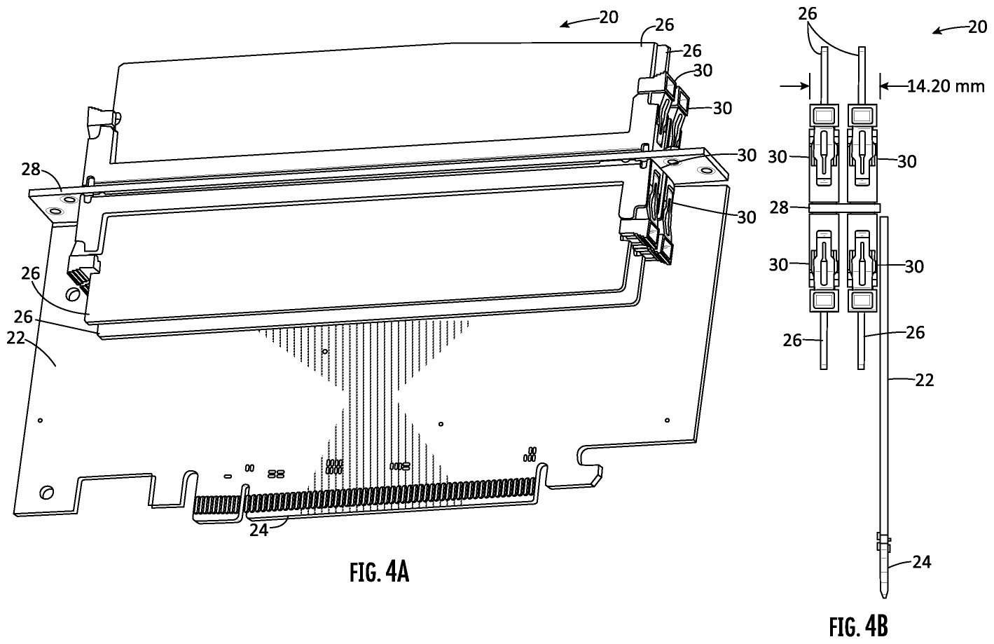

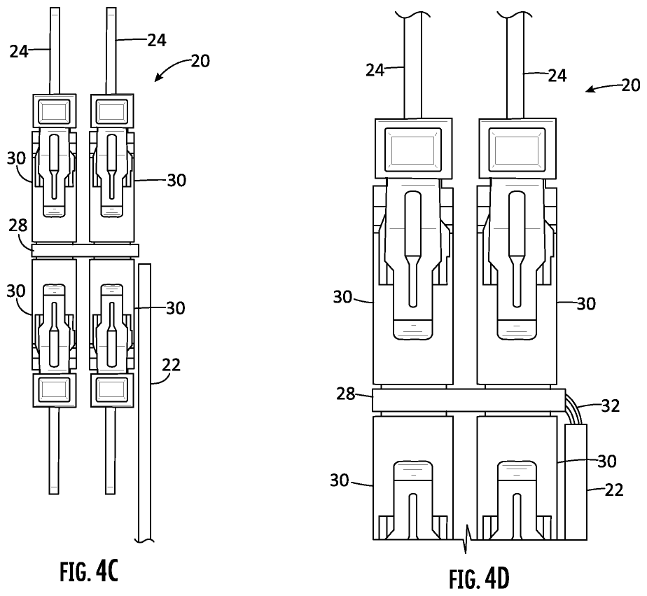

FIG. 4A is a schematic diagram of a single-slot PCIe card 20 with expanded memory according to embodiments described herein. The single-slot PCIe card 20 includes a first circuit board 22, which has a PCIe connector 24 for interfacing with a PCIe socket on a computer motherboard or other device. The first circuit board 22 may have a standardized shape according to the PCIe standard.

In order to accommodate expanded memory (e.g., additional memory modules 26), a second circuit board 28 is electrically connected to the first circuit board 22. The second circuit board 28 is angled transverse (e.g., perpendicular, at 90 degrees±15 degrees, or at 90 degrees±5 degrees) to the first circuit board 26 and has one or more DIMM sockets 30 (e.g., configured to receive full-length DIMMs). In an exemplary aspect, the second circuit board 28 has three or more (e.g., 4) DIMM sockets 30 mounted transverse thereto, such that the memory modules 26 are parallel to the first circuit board 22 when inserted. One or more (e.g., two) DIMM sockets 30 may be mounted on a first major surface of the second circuit board 28, and one or more (e.g., two) DIMM sockets 30 may be mounted on a second major surface of the second circuit board 28 opposite the first major surface.

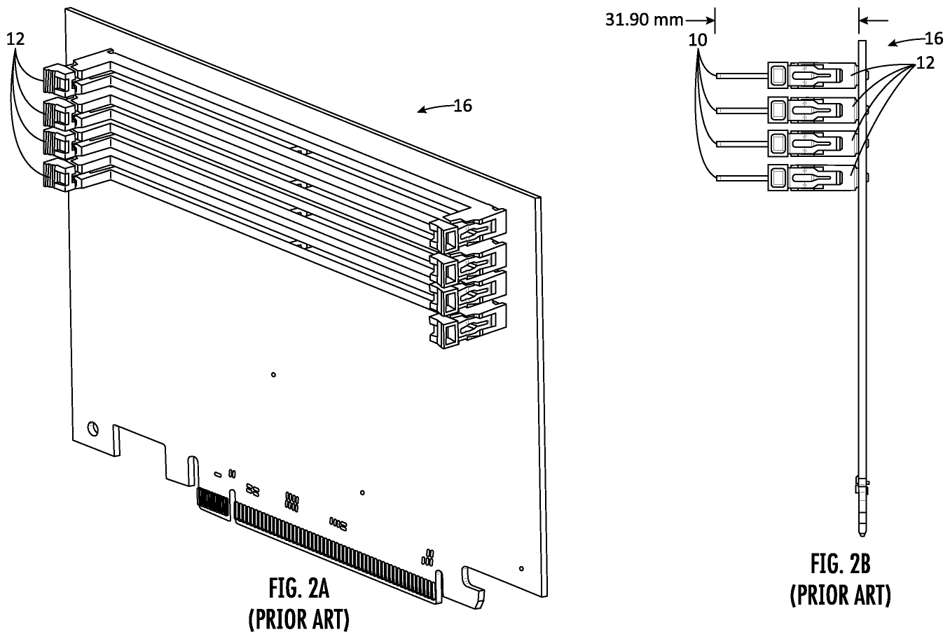

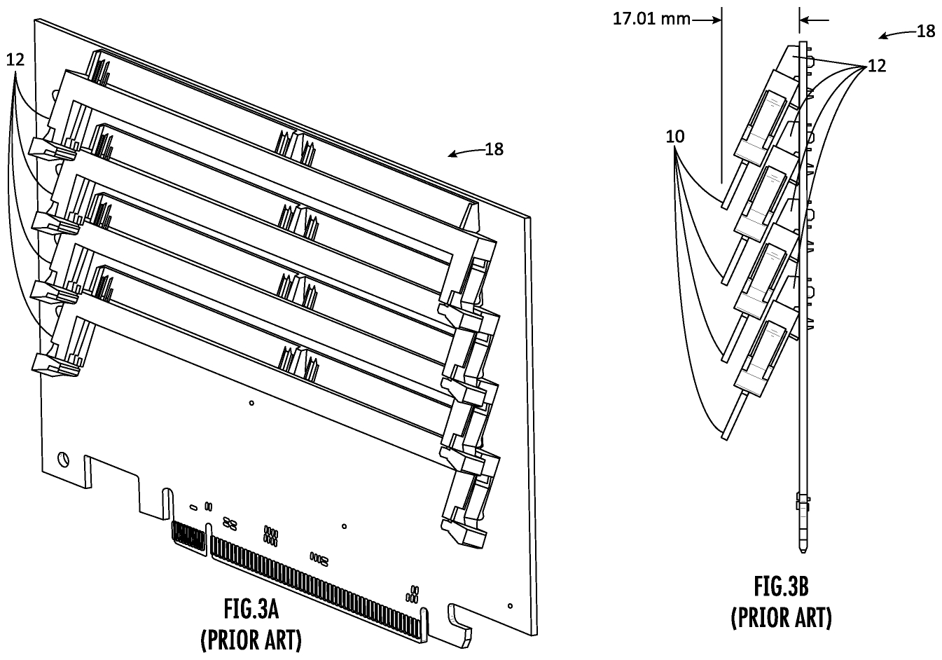

FIG. 4B is a side view of the single-slot PCIe card 20 of FIG. 4A. Embodiments described herein allow a PCIe card to have four memory modules 26 (e.g., DIMMs) while meeting the PCIe single slot primary side height maximum of 14.47 millimeters (mm). By having the DIMM sockets 30 placed horizontally relative to the first circuit board 22, the overall height of the single-slot PCIe card 20 is lowered relative to the approaches of FIGS. 2A-3B. In an exemplary embodiment, the single-slot PCIe card 20, with memory modules 26 installed, has a primary side height of 14.20 mm, meeting the PCIe single slot primary side height requirement.

FIG. 4C is an expanded side view of the single-slot PCIe card 20 of FIG. 4A. FIG. 4D is another expanded side view of the single-slot PCIe card of FIG. 4A. As described above, the single-slot PCIe card 20 uses two rigid boards (e.g., the first circuit board 22 and second circuit board 28) which are oriented perpendicular to each other. The first circuit board 22 and second circuit board 28 may be printed circuit boards (PCBs) and are connected by a flexible cable 32.

In an exemplary aspect, the flexible cable 32 is sandwiched between the laminates of the first circuit board 22 and the second circuit board 28. The flexible cable 32 provides a high-speed signal connection and a high-power connection between the first circuit board 22 and the second circuit board 28. In particular, the flexible cable 32 provides a high-speed memory channel for each DIMM socket 30 on the second circuit board 28, such as four high-speed memory channels for the illustrated embodiment.

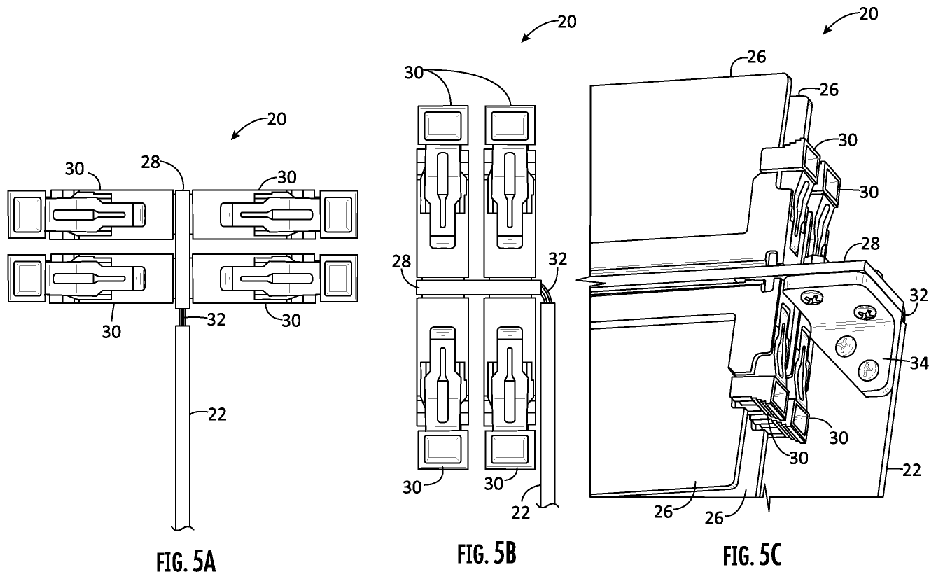

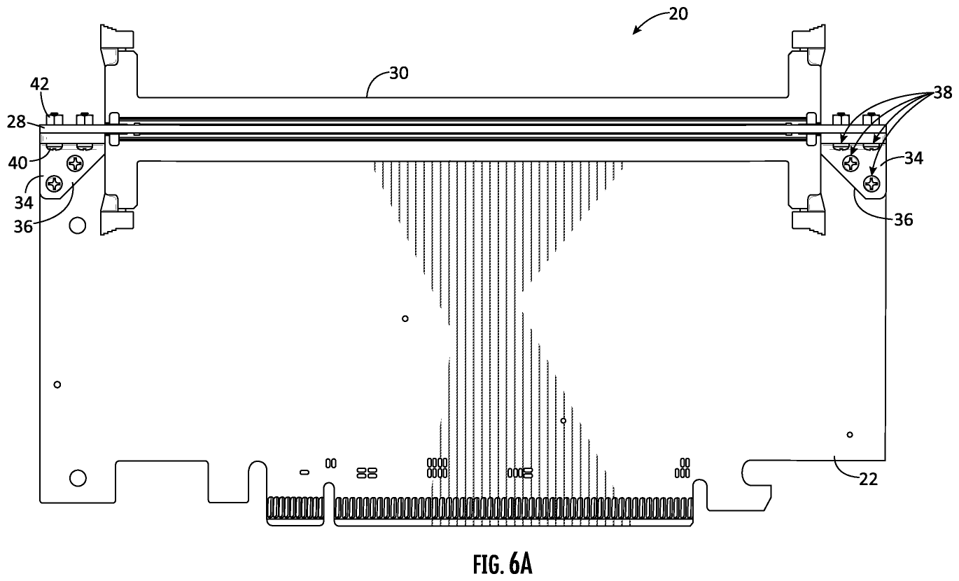

FIG. 5A is a side view of the single-slot PCIe card 20 with the second circuit board 28 aligned with the first circuit board 22. FIG. 5B is a side view of the single-slot PCIe card 20 with the second circuit board 28 transverse to the first circuit board 22. The flexible cable 32 needs to bend 90 degrees (±15 degrees) in order for the first circuit board 22 and the second circuit board 28 to be perpendicular to each other. The flexible cable 32 can be rigid flex or similar and can maintain impedance consistent to reduce the signal integrity return loss and insertion loss of other connectors. The flexible cable 32 can provide solid reference ground planes to reduce the noise coupling at a connector and can support enough power/ground layers and signal connections per needed to maintain better signal integrity.

FIG. 5C is a side view of the single-slot PCIe card 20 with the second circuit board 28 secured to the first circuit board 22 with a mechanical retainer 34. After bending the flexible cable 32, the first circuit board 22 and the second circuit board 28 can be secured by one or more mechanical retainers 34, which may be attached via screws, rivets, adhesive, or another appropriate technique. The mechanical retainer 34 maintains the angle of the second circuit board 28 and constrains its position so that all memory modules 26 can be inserted into the DIMM sockets 30 without causing any displacement or damage to the flexible cable 32.

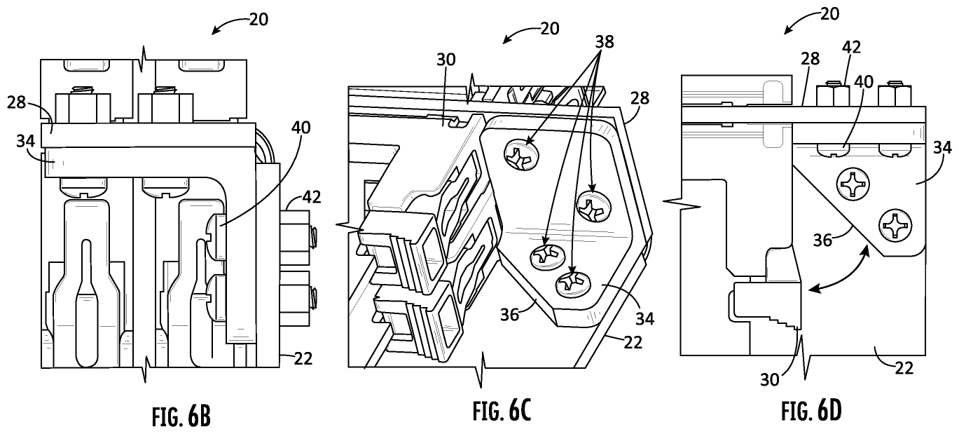

FIG. 6A is a schematic diagram of the single-slot PCIe card 20 with the second circuit board 28 secured to the first circuit board 22 with mechanical retainers 34. FIG. 6B is a side view of the mechanical retainer 34 securing the second circuit 28 board to the first circuit board 22. FIG. 6C is an isometric view of the mechanical retainer 34 securing the second circuit board 28 to the first circuit board 22. FIG. 6D is a top view of the mechanical retainer 34 securing the second circuit board 28 to the first circuit board 22.

The mechanical retainer 34 has an L-shape so as not to impede the airflow to the memory modules 26 such that heat dissipation will be effective. The mechanical retainer 34 also has features 36 (e.g., an angled corner) which will not impede the opening and closing of the socket latch of the DIMM sockets 30. When placed adjacent to the DIMM sockets 30, the mechanical retainer 34 can also act as a shock and vibration retainer.

In an exemplary aspect, the mechanical retainer 34 is made from aluminum (or another metal, plastic, or other rigid material) and anodized to avoid electrical conductivity. Each mechanical retainer 34 can have four mounting locations 38, each of which may be secured by a screw 40 and retaining nut 42.

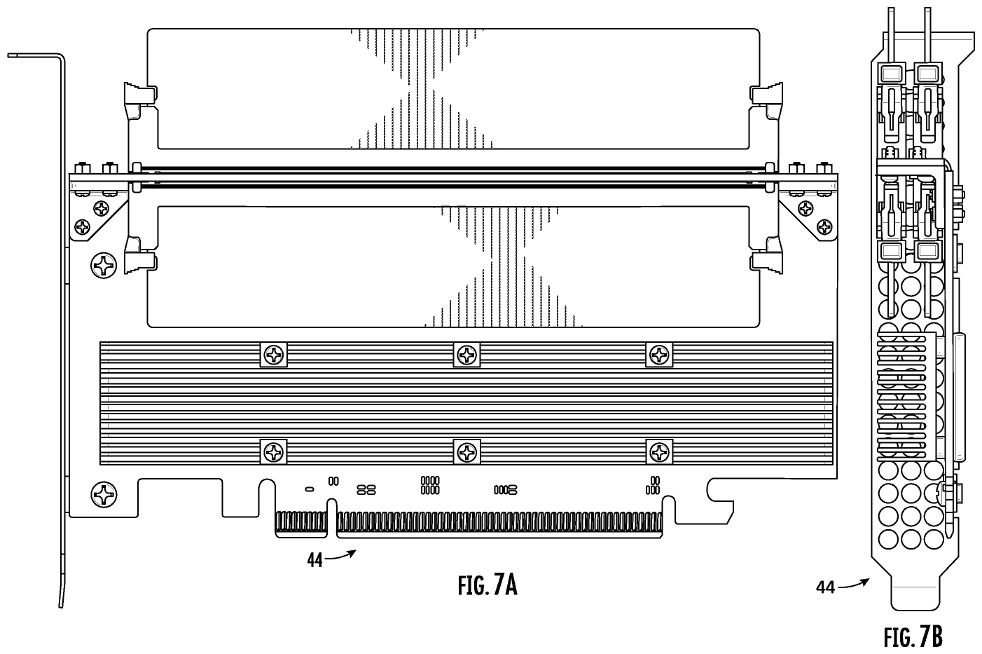

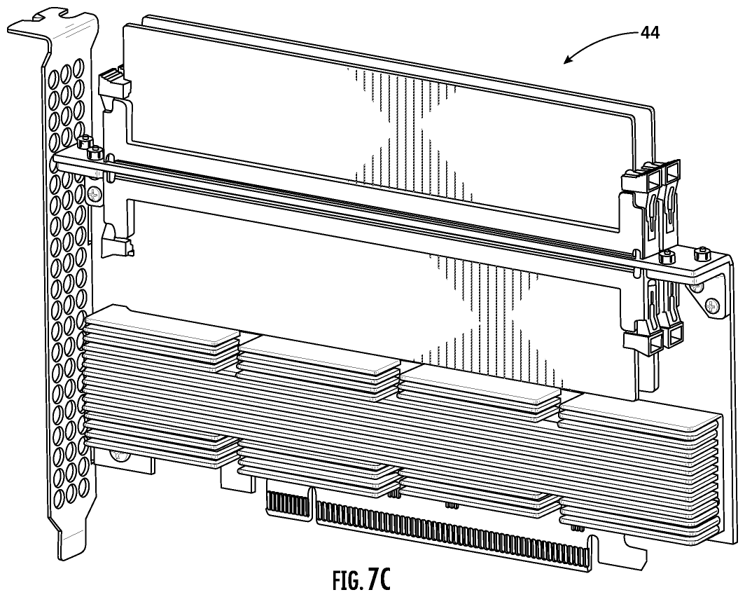

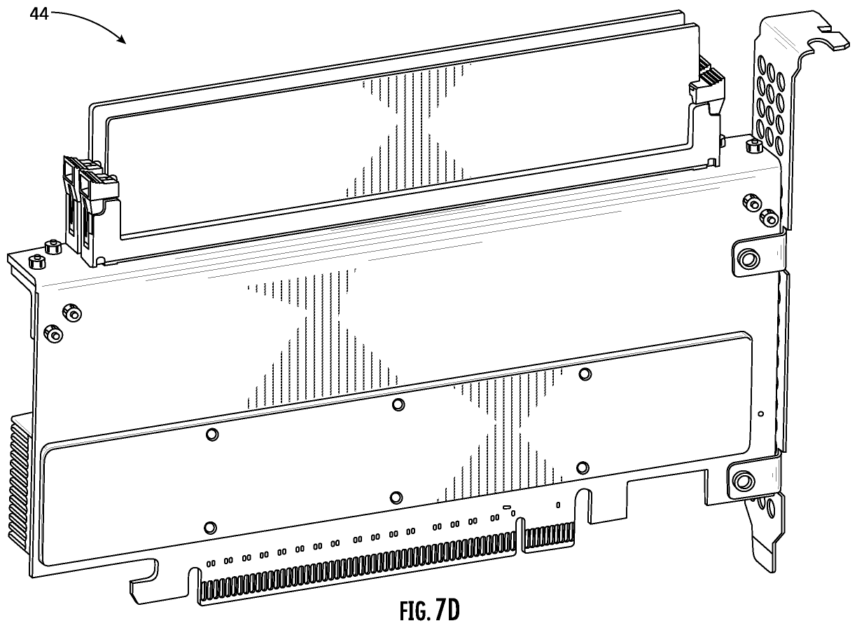

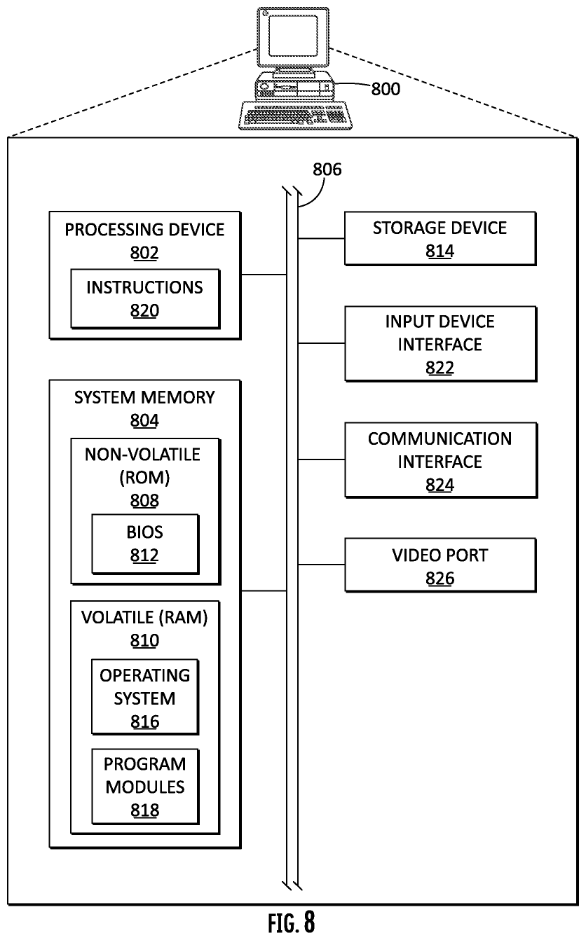

FIG. 7A is a top view of a memory expansion card 44 according to embodiments described herein. The memory expansion card 44 is a PCIe card as described above and may include a memory control circuitry and other components to support a PCIe connection for three or more random-access memory (RAM) modules, which may be dynamic RAM (DRAM), such as synchronous DRAM (SDRAM) or double data rate (DDR) SDRAM (e.g., DDR1, DDR2, DDR3, DDR4, DDR5) modules.

FIG. 7B is a side view of the memory expansion card 44 of FIG. 7A. FIG. 7C is a top isometric view of the memory expansion card of FIG. 7A. FIG. 7D is a bottom isometric view of the memory expansion card of FIG. 7A.

It should be understood that exemplary embodiments have been described with respect to PCIe cards with expanded memory slots, but can also be used in any other products which require a similar PCB extension to include additional components while maintaining a particular primary side height, such as single slot.

FIG. 8 is a block diagram of a computer system 800 according to embodiments disclosed herein. The computer system 800 comprises any computing or electronic device capable of including firmware, hardware, and/or executing software instructions. In this regard, the computer system 800 may be a circuit or circuits included in an electronic board card, such as a printed circuit board (PCB), a server, a personal computer, a desktop computer, a laptop computer, an array of computers, a personal digital assistant (PDA), a computing pad, a mobile device, or any other device, and may represent, for example, a server or a user's computer.

The exemplary computer system 800 in this embodiment includes a processing device 802 or processor, a system memory 804, and a system bus 806. The processing device 802 represents one or more commercially available or proprietary general-purpose processing devices, such as a microprocessor, central processing unit (CPU), or the like. More particularly, the processing device 802 may be a complex instruction set computing (CISC) microprocessor, a reduced instruction set computing (RISC) microprocessor, a very long instruction word (VLIW) microprocessor, a processor implementing other instruction sets, or other processors implementing a combination of instruction sets. The processing device 802 is configured to execute processing logic instructions for performing the operations and steps discussed herein.

In this regard, the various illustrative logical blocks, modules, and circuits described in connection with the embodiments disclosed herein may be implemented or performed with the processing device 802, which may be a microprocessor, field programmable gate array (FPGA), a digital signal processor (DSP), an application-specific integrated circuit (ASIC), or other programmable logic device, a discrete gate or transistor logic, discrete hardware components, or any combination thereof designed to perform the functions described herein. Furthermore, the processing device 802 may be a microprocessor, or may be any conventional processor, controller, microcontroller, or state machine. The processing device 802 may also be implemented as a combination of computing devices (e.g., a combination of a DSP and a microprocessor, a plurality of microprocessors, one or more microprocessors in conjunction with a DSP core, or any other such configuration).

The system memory 804 may include non-volatile memory 808 and volatile memory 810. The non-volatile memory 808 may include read-only memory (ROM), erasable programmable read-only memory (EPROM), electrically erasable programmable read-only memory (EEPROM), and the like. The volatile memory 810 generally includes RAM (e.g., DRAM, such as SDRAM). A basic input/output system (BIOS) 812 may be stored in the non-volatile memory 808 and can include the basic routines that help to transfer information between elements within the computer system 800.

The system bus 806 provides an interface for system components including, but not limited to, the system memory 804 and the processing device 802. The system bus 806 may be any of several types of bus structures that may further interconnect to a memory bus (with or without a memory controller), a peripheral bus, and/or a local bus using any of a variety of commercially available bus architectures.

The computer system 800 may further include or be coupled to a non-transitory computer-readable storage medium, such as a storage device 814, which may represent an internal or external hard disk drive (HDD), flash memory, or the like. The storage device 814 and other drives associated with computer-readable media and computer-usable media may provide non-volatile storage of data, data structures, computer-executable instructions, and the like. Although the description of computer-readable media above refers to an HDD, it should be appreciated that other types of media that are readable by a computer, such as optical disks, magnetic cassettes, flash memory cards, cartridges, and the like, may also be used in the operating environment, and, further, that any such media may contain computer-executable instructions for performing novel methods of the disclosed embodiments.

An operating system 816 and any number of program modules 818 or other applications can be stored in the volatile memory 810, wherein the program modules 818 represent a wide array of computer-executable instructions corresponding to programs, applications, functions, and the like that may implement the functionality described herein in whole or in part, such as through instructions 820 on the processing device 802. The program modules 818 may also reside on the storage mechanism provided by the storage device 814. As such, all or a portion of the functionality described herein may be implemented as a computer program product stored on a transitory or non-transitory computer-usable or computer-readable storage medium, such as the storage device 814, volatile memory 810, non-volatile memory 808, instructions 820, and the like. The computer program product includes complex programming instructions, such as complex computer-readable program code, to cause the processing device 802 to carry out the steps necessary to implement the functions described herein.

An operator, such as the user, may also be able to enter one or more configuration commands to the computer system 800 through a keyboard, a pointing device such as a mouse, or a touch-sensitive surface, such as the display device, via an input device interface 822 or remotely through a web interface, terminal program, or the like via a communication interface 824. The communication interface 824 may be wired or wireless and facilitate communications with any number of devices via a communications network in a direct or indirect fashion. An output device, such as a display device, can be coupled to the system bus 806 and driven by a video port 826. Additional inputs and outputs to the computer system 800 may be provided through the system bus 806 as appropriate to implement embodiments described herein.

The operational steps described in any of the exemplary embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary embodiments may be combined.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A peripheral component interconnect express (PCIe) card, comprising:
a first circuit board comprising a PCIe connector; and
a second circuit board electrically connected with the first circuit board and angled transverse to the first circuit board, the second circuit board comprising a dual in-line memory module (DIMM) socket.

2. The PCIe card of claim 1, wherein the PCIe card is a single-slot PCIe card.

3. The PCIe card of claim 2, wherein the second circuit board comprises three or more DIMM sockets and meets a single-slot PCIe primary side height requirement while a memory module is inserted in each DIMM socket.

4. The PCIe card of claim 3, wherein:
at least one of the three or more DIMM sockets is disposed on a first major surface of the second circuit board; and
at least one of the three or more DIMM sockets is disposed on a second major surface of the second circuit board opposite the first major surface.

5. The PCIe card of claim 2, wherein the second circuit board comprises four DIMM sockets and meets a single-slot PCIe primary side height requirement while a memory module is inserted in each DIMM socket.

6. The PCIe card of claim 1, further comprising a flexible cable connecting the first circuit board and the second circuit board.

7. The PCIe card of claim 6, wherein the flexible cable comprises a plurality of memory channels supporting a plurality of DIMM sockets on the second circuit board.

8. The PCIe card of claim 6, wherein the flexible cable is sandwiched between laminate layers of the first circuit board and the second circuit board.

9. The PCIe card of claim 1, further comprising a mechanical retainer configured to secure the second circuit board to the first circuit board.

10. The PCIe card of claim 9, wherein the mechanical retainer maintains an angle of 90 degrees±15 degrees between the first circuit board and the second circuit board.

11. A single-slot peripheral component interconnect express (PCIe) card, comprising:
a first circuit board comprising a PCIe connector; and
a second circuit board electrically connected with the first circuit board and comprising three or more dual in-line memory module (DIMM) sockets.

12. The single-slot PCIe card of claim 11, wherein the second circuit board is angled relative to the first circuit board.

13. The single-slot PCIe card of claim 12, wherein the second circuit board is angled transverse to the first circuit board.

14. The single-slot PCIe card of claim 12, further comprising a flexible electrical connection between the first circuit board and the second circuit board.

15. The single-slot PCIe card of claim 14, wherein the flexible electrical connection comprises a plurality of memory channels supporting the three or more DIMM sockets on the second circuit board.

16. The single-slot PCIe card of claim 14, wherein the flexible electrical connection exits from one or more laminate layers of the first circuit board.

17. A computer peripheral card, comprising:
a first circuit board comprising laminate layers;
a second circuit board angled transverse to the first circuit board, the second circuit board comprising a memory module connector; and
a flexible electrical connection between the first circuit board and the second circuit board, wherein the flexible electrical connection exits the first circuit board between the laminate layers of the first circuit board.

18. The computer peripheral card of claim 17, wherein the memory module connector is a dual in-line memory module (DIMM) socket.

19. The computer peripheral card of claim 17, wherein:
the second circuit board comprises laminate layers; and
the flexible electrical connection enters the second circuit board between the laminate layers of the second circuit board.

20. The computer peripheral card of claim 17, wherein the computer peripheral card is a single-slot peripheral component interconnect express (PCIe) card.
